(19) United States
(12) Patent Application Publication
(10) Pub. No.: US 2015/0043189 A1
(43) Pub. Date: Feb. 12, 2015

(54) CIRCUIT MODULE AND METHOD OF PRODUCING THE SAME

(71) Applicant: Taiyo Yuden Co., Ltd., Tokyo (JP)

(72) Inventors: Kenzo KITAZAKI, Tokyo (JP); Masaya SHIMAMURA, Tokyo (JP); Eiji MUGIYA, Tokyo (JP); Takehiko KAI, Tokyo (JP)

(73) Assignee: Taiyo Yuden Co., Ltd., Tokyo (JP)

(21) Appl. No.: 14/102,212

(22) Filed: Dec. 10, 2013

(30) Foreign Application Priority Data
Aug. 12, 2013 (JP) 2013-167408

(51) Int. Cl. H05K 9/00; H05K 3/28

(52) U.S. Cl. CPC H05K 9/0081; H05K 3/284
USPC 361/816; 29/832

(57) ABSTRACT

A circuit module includes a wiring substrate having a mount surface and a conductor pattern, the mount surface having first and second areas, the conductor pattern being formed along a boundary between the first and second areas on the mount surface, an outermost layer of the conductor pattern including Au or Ag; a plurality of electronic components mounted on the first and second areas; an insulating sealing layer formed along the boundary, the insulating sealing layer having a trench with a depth such that at least a part of the outermost layer of the conductor pattern is exposed, the insulating sealing layer covering the electronic components; and a conductive shield having first and second shield portions, the first shield portion covering an outer surface of the sealing layer, the second shield portion being formed at the trench, the second shield portion being electrically connected to the conductor pattern.

### CROSS-REFERENCE TO A RELATED APPLICATION

This application claims priority under 35 U.S.C. §119 to Japanese Patent Application No. JP 2013-167408 filed on Aug. 12, 2013, the entire content of which is hereby incorporated herein by reference in its entirety

### FIELD

The present disclosure relates to a circuit module having an electromagnetic shielding function and to a method of producing the circuit module.

### BACKGROUND

A circuit module in which a plurality of electronic components are mounted on a substrate, which is installed in various electronic apparatuses, has been known. In general, such a circuit module employs a configuration that has an electromagnetic shielding function to prevent an electromagnetic wave from leaking to the outside of the module and entering from the outside.

Furthermore, with diversification and high-functionalization of the electronic components mounted in the circuit module, various measures for preventing the electronic components from electromagnetically interfere with each other have been proposed. For example, Japanese Patent Application Laid-open No. 2010-225620 describes a circuit module in which a slit penetrating a mold resin layer to reach a circuit substrate is formed between two electronic components on the circuit substrate and the slit is filled with conductive resin. Moreover, Japanese Patent Application Laid-open No. 2012-019091 describes a module in which a shield conductor wall between circuit blocks is formed of a plurality of conductor components mounted on a circuit substrate or of a conductor paste or conductor paint filled in a groove formed in mold resin.

### SUMMARY

In the configuration described in Japanese Patent Application Laid-open No. 2010-225620, however, because the slit penetrating the mold resin layer is formed by a dicing process, the shape of the slit is limited to a linear shape and it may be impossible to form a curved or branched slit. The shape of an inner shield and the mounting layout of components are limited. Furthermore, because it may be impossible to control the depth of the slit with a high accuracy in the dicing process, it is difficult to electrically connect the bottom of the slit and a wiring layer located immediately below the slit.

On the other hand, in the configuration described in Japanese Patent Application Laid-open No. 2012-019091, because the shield conductor wall is formed of the plurality of conductor components mounted on the circuit substrate, it may be impossible to suppress the increase in the production cost due to increase in the number of components and the number of mounting man-hours.

Moreover, Japanese Patent Application Laid-open No. 2012-019091 describes that the groove to be filled with a conductor paste or conductor paint is formed by laser processing of mold resin. In the method, the strength of the laser beam is adjusted and then the above-mentioned groove is formed. However, if the intensity of the laser beam is too high, it may be impossible to prevent the wiring on the substrate from being damaged. On the other hand, if the strength of the laser beam is too low, the efficiency of the process of mold resin is reduced and it may be impossible to ensure the productivity. Therefore, the method has a problem of a difficulty in setting an optimal laser intensity.

In view of the circumstances as described above, it is desirable to provide a circuit module with a high degree of freedom of designing of the shield shape, which is capable of protecting the wiring on the substrate against irradiation of a laser beam and ensuring the electrical connection between the wiring layer and the shield, and a method of producing the circuit module.

According to an embodiment of the present disclosure, there is provided a circuit module including a wiring substrate, a plurality of electronic components, a sealing layer, and a conductive shield.

The wiring substrate has a mount surface and a conductor pattern, the mount surface having a first area and a second area, the conductor pattern being formed along a boundary between the first area and the second area on the mount surface, an outermost layer of the conductor pattern including one of Au and Ag.

The plurality of electronic components are mounted on the first area and the second area.

The sealing layer includes an insulating material, the sealing layer being formed along the boundary, the sealing layer having a trench with a depth such that at least a part of the outermost layer of the conductor pattern is exposed, the sealing layer covering the plurality of electronic components.

The conductive shield has a first shield portion and a second shield portion, the first shield portion covering an outer surface of the sealing layer, the second shield portion being formed at the trench, the second shield portion being electrically connected to the conductor pattern.

Moreover, according to an embodiment of the present disclosure, there is provided a method of producing a circuit module including preparing a wiring substrate on which a conductor pattern is formed on a mount surface having a first area and a second area, the conductor pattern being formed along a boundary between the first area and the second area on the mount surface, the conductor pattern being electrically connected to a terminal surface on the opposite side of the mount surface.

One of an Au layer and an Ag layer is formed on a surface of the conductor pattern.

A plurality of electronic components are mounted on the first area and the second area.

A sealing layer including an insulating material is formed on the mount surface, the sealing layer covering the plurality of electronic components.

A trench is formed on the sealing layer by applying a laser beam to a surface of the sealing layer, the trench having a depth such that at least a part of an outermost surface of the conductor pattern is exposed.

A conductive shield is formed by filling conductive resin in the trench and covering an outer surface of the sealing layer with conductive resin.

These and other objects, features and advantages of the present disclosure will become more apparent in light of the following detailed description of best mode embodiments thereof, as illustrated in the accompanying drawings.

### BRIEF DESCRIPTION OF THE DRAWINGS

FIG. 1 is a plan view of a circuit module according to an embodiment of the present disclosure;

FIG. 2 is a cross-sectional view taken along the direction of line A-A in FIG. 1;

FIG. 3 is an enlarged cross-sectional view of a main portion of the circuit module;

FIG. 4 is a diagram for explaining a method of producing the circuit module;

FIGS. 5A and 5B are diagrams for explaining the method of producing the circuit module, FIG. 5A is a plan view showing a process of disposing electronic components, and FIG. 5B is a cross-sectional view of a main portion thereof;

FIGS. 6A and 6B are diagrams for explaining the method of producing the circuit module, FIG. 6A is a plan view showing a process of forming a sealing layer, and FIG. 6B is a cross-sectional view of a main portion thereof;

FIGS. 7A and 7B are diagrams for explaining the method of producing the circuit module, FIG. 7A is a plan view showing a half-cutting process, and FIG. 7B is a cross-sectional view of a main portion thereof;

FIGS. 8A and 8B are diagrams for explaining the method of producing the circuit module, FIG. 8A is a plan view showing a process of forming a trench, and FIG. 8B is a cross-sectional view of a main portion thereof;

FIGS. 9A and 9B are diagrams for explaining the method of producing the circuit module, FIG. 9A is a plan view showing a process of forming a conductive shield, and FIG. 9B is a cross-sectional view of a main portion thereof; and

FIGS. 10A and 10B are diagrams for explaining the method of producing the circuit module, FIG. 10A is a plan view showing a dividing process, and FIG. 10B is a cross-sectional view of a main portion thereof.

### DETAILED DESCRIPTION OF EMBODIMENTS

A circuit module according to an embodiment of the present disclosure includes a wiring substrate, a plurality of electronic components, a sealing layer, and a conductive shield.

The wiring substrate has a mount surface and a conductor pattern, the mount surface having a first area and a second area, the conductor pattern being formed along a boundary between the first area and the second area on the mount surface, an outermost layer of the conductor pattern including one of Au and Ag.

The plurality of electronic components are mounted on the first area and the second area.

The sealing layer includes an insulating material, the sealing layer being formed along the boundary, the sealing layer having a trench with a depth such that at least a part of the outermost layer of the conductor pattern is exposed, the sealing layer covering the plurality of electronic components.

The conductive shield has a first shield portion and a second shield portion, the first shield portion covering an outer surface of the sealing layer, the second shield portion being formed at the trench, the second shield portion being electrically connected to the conductor pattern.

Because the outermost layer of the conductor pattern includes Au (gold) or Ag (silver), the conductor pattern has high reflectance properties with respect to a laser beam such as an Nd:YAG laser (having a wavelength of 1064 nm) as compared with other metals such as Cu. Therefore, in the case where the above-mentioned laser beam is used to form the trench on the resin layer, it is possible to effectively protect the conductor pattern against burnout or cutting due to irradiation of the laser beam. Accordingly, the electrical connection between the conductor pattern and the second shield portion provided in the trench is ensured, and the degree of freedom of designing of the shield shape is increased because the trench can be formed in an arbitrary shape.

The wiring substrate may further have a terminal surface disposed on the opposite side of the mount surface, the conductor pattern being electrically connected to the terminal surface.

Accordingly, it is possible to improve the shielding properties of the second shield portion because the conductor pattern can be connected to a ground potential via the control substrate of the electronic apparatus.

The wiring substrate may further have an insulating protective layer covering the mount surface, the protective layer having an aperture from which at least a part of the outermost layer of the conductor pattern is exposed.

Accordingly, it is possible to easily form an Au layer or an Ag layer on the surface of the conductor pattern. Furthermore, it is possible to improve the adhesiveness of the sealing layer to the mount surface by the protective layer.

The conductor pattern may have a single-layer structure including Au or Ag, or may include a laminated body of two or more metals. Typically, the conductor pattern has a first metal layer including Cu (copper), and a second metal layer including one of Au and Ag, the second metal layer being formed on a surface of the first metal layer. Accordingly, it is possible to form the wiring substrate at a relatively low cost, and to selectively form an Au layer or an Ag layer in an appropriate area.

The conductor pattern further may have a third metal layer disposed between the first metal layer and the second metal layer, the third metal layer including a metal material having a melting point higher than Cu.

Accordingly, the heat resistance of the conductor pattern is improved, and the above-mentioned first metal layer can be protected by the above-mentioned third metal layer even in the case where the above-mentioned second metal layer is burned out by the irradiation of a laser beam.

The second shield portion may include a cured material of conductive resin filled in the trench, or one of a plated layer and a sputtered layer deposited on an inner wall of the trench.

As the laser beam, various laser beams such as a gas laser, a solid laser, and a semiconductor laser, which are used as a laser for processing, can be employed. It is favorable to use a laser beam having a wavelength at which Au or Ag has higher reflectance properties and lower absorption properties than other metals (e.g., 500 nm or more), and an Nd:YAG laser, and Nd:YVO₄ laser, a CO₂ laser or the like is typically employed. Accordingly, it is possible to form the trench in an arbitrary shape while protecting the conductor pattern appropriately. Furthermore, by using a laser beam having a relatively long wavelength, it is possible to reduce the absorption of the laser beam to each metal layer, and to reduce the damage on each metal layer due to the irradiation of the laser beam.

A method of producing a circuit module according to an embodiment of the present disclosure includes preparing a wiring substrate on which a conductor pattern is formed on a mount surface having a first area and a second area, the conductor pattern being formed along a boundary between the first area and the second area on the mount surface, the conductor pattern being electrically connected to a terminal surface on the opposite side of the mount surface.

One of an Au layer and an Ag layer is formed on a surface of the conductor pattern.

A plurality of electronic components are mounted on the first area and the second area.

A sealing layer including an insulating material is formed on the mount surface, the sealing layer covering the plurality of electronic components.

A trench is formed on the sealing layer by applying a laser beam to a surface of the sealing layer, the trench having a depth such that at least a part of an outermost surface of the conductor pattern is exposed.

A conductive shield is formed by filling conductive resin in the trench and covering an outer surface of the sealing layer with conductive resin.

The forming of one of the Au layer and the Ag layer may include forming, on the mount surface, an insulating protective layer having an aperture from which at least a part of the outermost layer of the conductor pattern is exposed, and forming one of the Au layer and the Ag layer using the protective layer as a mask, for example.

Accordingly, it is possible to easily form one of the Au layer and the Ag layer on the surface of the conductor pattern. Furthermore, it is possible to improve the adhesiveness of the sealing layer to the mount surface by the protective layer.

The trench may be formed by applying an Nd:YAG laser beam to a surface of the sealing layer. Accordingly, it is possible to form the trench in an arbitrary shape while protecting the conductor pattern appropriately. Furthermore, it is possible to reduce the absorption of the laser beam to each metal layer by using a laser beam having a relatively long wavelength, and to reduce the damage on each metal layer due to the irradiation of the laser beam.

According to the method of producing a circuit module, because the forming of the trench is performed by a laser processing method, it is possible to form the trench in an arbitrary shape as compared with the case where the trench is formed by a dicing process, for example. Accordingly, it is possible to increase the degree of freedom of designing of the shield shape. Moreover, because an Au layer or Ag layer is provided on the outermost layer of the area in which the trench is formed, it is possible to protect the wiring substrate and the conductor pattern formed on the surface thereof against irradiation of the laser beam.

Hereinafter, embodiments according to the present disclosure will be described with reference to the drawings.

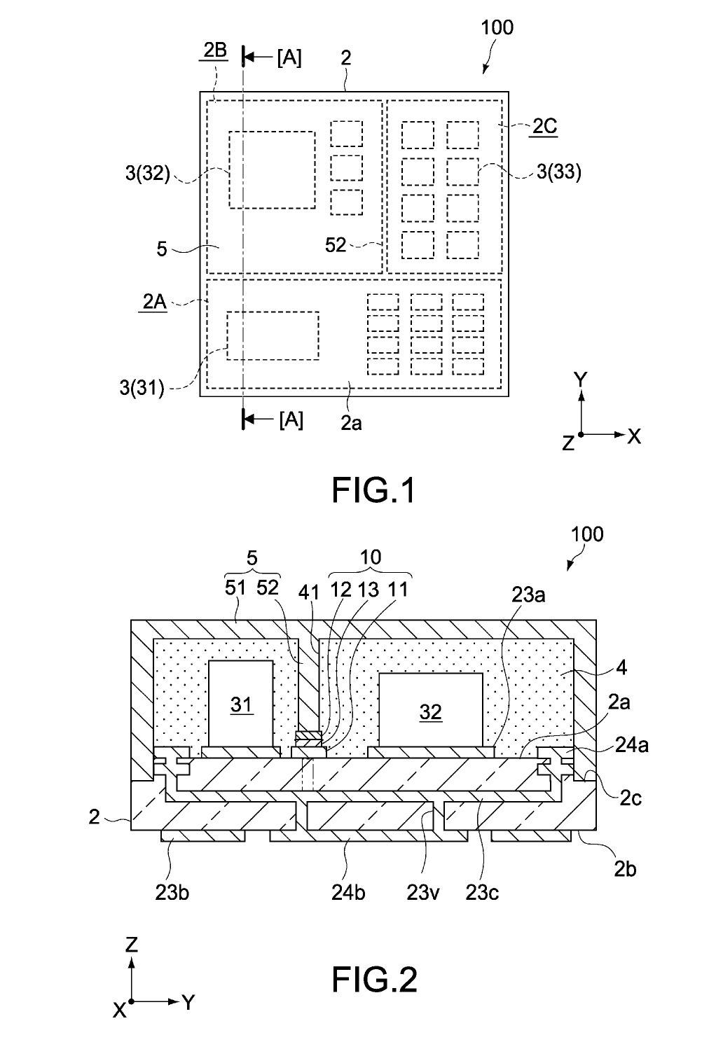

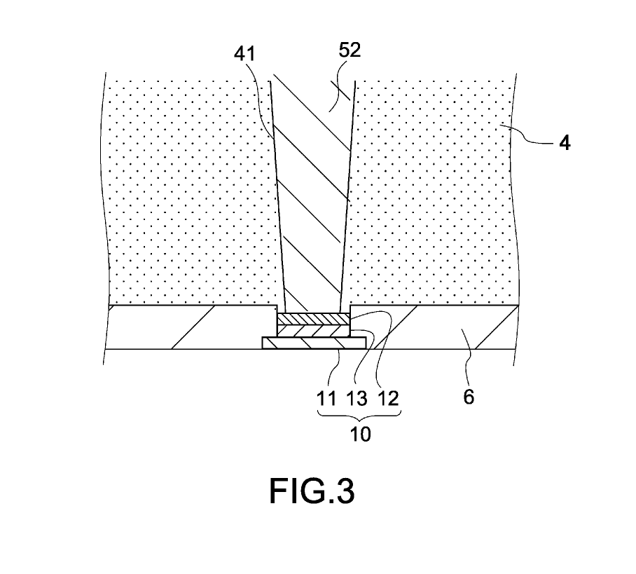

FIGS. 1 to 3 are diagrams showing a circuit module according to an embodiment of the present disclosure, FIG. 1 is a top view, FIG. 2 is a cross-sectional view taken along the direction of line A-A in FIG. 1, and FIG. 3 is an enlarged cross-sectional view of FIG. 2.

It should be noted that in each figure, X-, Y-, and Z-axes represent triaxial directions orthogonal to each other, and the Z-axis direction corresponds to the thickness direction of the circuit module. It should be noted that the configuration of each portion is exaggeratingly shown in order to facilitate understanding, and the sizes of the members or the ratios of the sizes of the members do not necessarily correspond to each other in the figures.

### [Configuration of Circuit Module]

A circuit module 100 according to this embodiment includes a wiring substrate 2, a plurality of electronic components 3 (31 to 33), a sealing layer 4, and a conductive shield 5.

The circuit module 100 is formed in a substantially rectangular parallelepiped shape as a whole. The size of the circuit module 100 is not particularly limited, and the circuit module 100 is formed to have the length of 10 to 50 mm along the X-axis direction and the length of 10 to 50 mm along the Y-axis direction, for example. In this embodiment, the circuit module 100 is formed to have a substantially square shape having a side length of about 35 mm. Moreover, also the thickness of the circuit module 100 is not particularly limited, and the circuit module 100 is formed to have the thickness of 1 to 3 mm. In this embodiment, the circuit module 100 is formed to have the thickness of about 2 mm.

In the circuit module 100, the plurality of electronic components 3 are disposed on the wiring substrate 2, and the sealing layer 4 and the conductive shield 5 are formed so as to cover them. Hereinafter, the configuration of the respective portions of the circuit module 100 will be described.

### (Wiring Substrate)

The wiring substrate 2 includes a mount surface 2a formed to have a substantially square shape, which has the same size as the entire circuit module 100, for example, and a terminal surface 2b formed on the opposite side of the mount surface 2a. The wiring substrate 2 includes a glass epoxy multilayer wiring substrate having the thickness of about 0.4 mm, for example. The material forming the insulating layer of the wiring substrate 2 is not limited to the above-described glass epoxy material, and an insulating ceramic material can be employed, for example.

The wiring layer of the wiring substrate 2 typically includes a conductive material such as Cu, and is disposed on the surface, rear surface, and inner layer of the wiring substrate 2. The wiring layer is subjected to patterning into a predetermined shape to form an upper layer wiring pattern 23a disposed on the mount surface 2a, a lower layer wiring pattern 23b disposed on the terminal surface 2b, and an inner layer wiring pattern 23c disposed therebetween. The upper layer wiring pattern 23a includes a land portion on which the electronic component 3 is mounted, and a conductor pattern 10 connected to a second shield portion 52 (conductive shield 5). The lower layer wiring pattern 23b includes an external connection terminal connected to a control substrate (not shown) of the electronic apparatus on which the circuit module 100 is mounted. The layers of the wiring layer are electrically connected to each other via a via conductor 23v.

Moreover, the above-mentioned wiring layer includes a first GND terminal 24a and a second GND terminal 24b, which are connected to a ground (GND) potential. The first GND terminal 24a is disposed adjacent to an uneven surface 2c formed around the upper surface of the wiring substrate 2, and is connected to the inner surface of a first shield portion 51 (conductive shield 5) disposed on the uneven surface 2c. The first GND terminal 24a may be formed as a part of the upper layer wiring pattern 23a, or a part of the inner layer wiring pattern 23c.

The second GND terminal 24b is connected to the first GND terminal 24a via the inner layer wiring pattern 23c. The second GND terminal 24b is formed as a part of the lower layer wiring pattern 23b, and is connected to a ground wiring of the above-mentioned control substrate.

The mount surface 2a is divided into a plurality of areas by the second shield portion 52 (conductive shield 5), and includes a first area 2A, a second area 2B, and a third area 2C, in this embodiment. In the example shown in FIG. 1, the first to third areas 2A to 2C are formed to have different sizes and different rectangular shapes. However, the areas 2A to 2C may be formed to have another polygon shape such as a triangular shape and a pentagonal shape, a circular shape, or an arbitrary geometric shape such as an elliptical shape. Moreover, the number of areas partitioned on the mount surface 2a is not limited to three, and may be two or not less than four.

The conductor pattern 10 includes a first metal layer 11 being a lower layer, a second metal layer 12 being an outermost layer, and a third metal layer being disposed therebetween. The conductor pattern 10 is formed along the boundary between the areas on the mount surface 2a, and is electrically connected to the second shield portion 52.

The first metal layer 11 forms a part of the upper layer wiring pattern 23a, and typically includes Cu. The thickness of the first metal layer 11 is not particularly limited, and the first metal layer 11 has a thickness of 10 to 15 μm, for example. The first metal layer 11 is connected to the second GND terminal 24b on the terminal surface 2b via the via conductor 23v and the inner layer wiring pattern 23c.

The second metal layer 12 includes Au or Ag. In this embodiment, the second metal layer 12 includes Au. The thickness of the second metal layer 12 is not particularly limited, and the second metal layer 12 is formed to have a thickness that can protect the first metal layer 11 against a laser for processing of a trench 41 to be described later, e.g., 1 to 10 μm.

The third metal layer 13 includes a metal material having a melting point higher than the first metal layer 11. For example, in the case where the first metal layer 11 includes Cu, the third metal layer 13 includes Ni (nickel), Ti (titanium), Cr (chromium), or the like. The thickness of the third metal layer 13 is not also particularly limited, and is 1 to 10 μm, for example. The third metal layer 13 has a function to improve the heat resistance of the conductor pattern 10 and to protect the first metal layer 11 against irradiation of the laser beam in the case where the second metal layer 12 is burned out due to the irradiation of the above-mentioned laser for processing. It should be noted that the third metal layer 13 may be omitted as necessary.

The second metal layer 12 and the third metal layer 13 may include a plated layer or a sputtered layer, which is formed using, as a mask, the insulating protective layer 6 (see FIG. 3) including an aperture from which at least a part of the first metal layer 11 is exposed.

### (Electronic Component)

The plurality of electronic components 3 are mounted on the first, second, and third areas 2A, 2B, and 2C on the mount surface 2a. Typically, examples of the plurality of electronic components 3 include various components such as an integrated circuit (IC), a capacitor, an inductor, a resistor, a crystal oscillator, a duplexer, a filter, and a power amplifier.

These components include components that generate an electromagnetic wave around them during operation or components liable to be affected by the electromagnetic wave. Typically, these components are mounted on different areas partitioned by the second shield portion 52 (conductive shield 5). Hereinafter, the electronic component 3 and the plurality of electronic components 3 mounted on the first area 2A are also referred to as electronic component 31, and the electronic component 3 and the plurality of electronic components 3 mounted on the second area 2B are also referred to as electronic component 32. Then, the electronic component 3 and the plurality of electronic components 3 mounted on the third area 2C are also referred to as electronic component 33.

The plurality of electronic components 3 are typically mounted on the mount surface 2a by soldering, an adhesive, an anisotropy adhesive sheet, a bonding wire, or the like.

### (Sealing Layer)

The sealing layer 4 includes an insulating material formed on the mount surface 2a so as to cover the plurality of electronic components 31 and 32. The sealing layer 4 is divided into a first area 2A side, a second area 2B side, and a third area 2C side by the second shield portion 52. In this embodiment, the sealing layer 4 includes insulating resin such as epoxy resin to which silica or alumina is added. The method of forming the sealing layer 4 is not particularly limited, and the sealing layer 4 is formed by a molding method, for example.

The sealing layer 4 includes the trench 41 formed along the boundary between the first area 2A, the second area 2B, and the third area 2C. The trench 41 is formed along the Z-axis direction from the upper surface of the sealing layer 4 to have a predetermined depth. In this embodiment, the trench 41 is typically formed to have a depth such that the bottom surface of the trench 41 reaches the second metal layer 12 of the conductor pattern 10 disposed on the mount surface 2a. However, the trench 41 only has to be formed to have a depth such that at least a part of the bottom surface reaches the second metal layer 12.

The method of forming the trench 41 is not particularly limited. However, in this embodiment, the trench 41 is formed by a laser processing technique. The laser for processing is not particularly limited. However, in this embodiment, an Nd:YAG laser (having a wavelength of 1064 nm) is used as the laser for processing.

### (Conductive Shield)

The conductive shield 5 includes the first shield portion 51 and the second shield portion 52. The first shield portion 51 is formed so as to cover the outer surface (surface including the upper surface and side surface of the sealing layer 4; the same shall apply hereinafter) of the sealing layer 4, and functions as the exterior shield of the circuit module 100. The second shield portion 52 is provided in the trench 41 of the sealing layer 4, and functions as the interior shield of the circuit module 100.

The conductive shield 5 includes a cured material of conductive resin filled in the outer surface of the sealing layer 4 and the trench 41. More specifically, epoxy resin to which conductive particles such as Ag and Cu are added is employed. Alternatively, the conductive shield 5 may include a plated layer or a sputtered layer deposited in the outer surface of the sealing layer 4 and the inner wall of the trench 41.

With such a configuration, it is possible to form the first shield portion 51 and the second shield portion 52 in the same process. Moreover, it is possible to form the first shield portion 51 and the second shield portion 52 integrally.

### [Method of Producing Circuit Module]

Next, a method of producing the circuit module 100 according to this embodiment will be described.

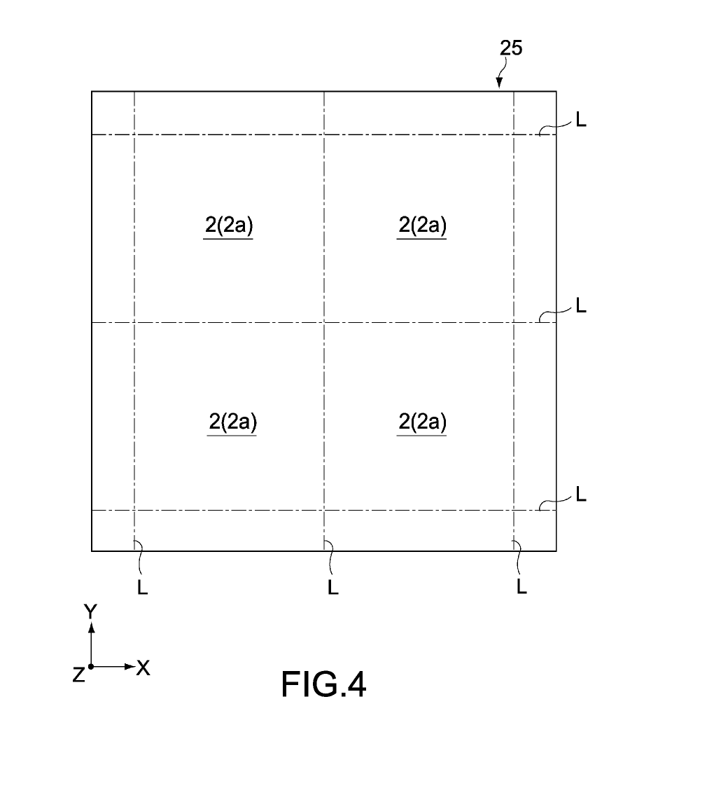

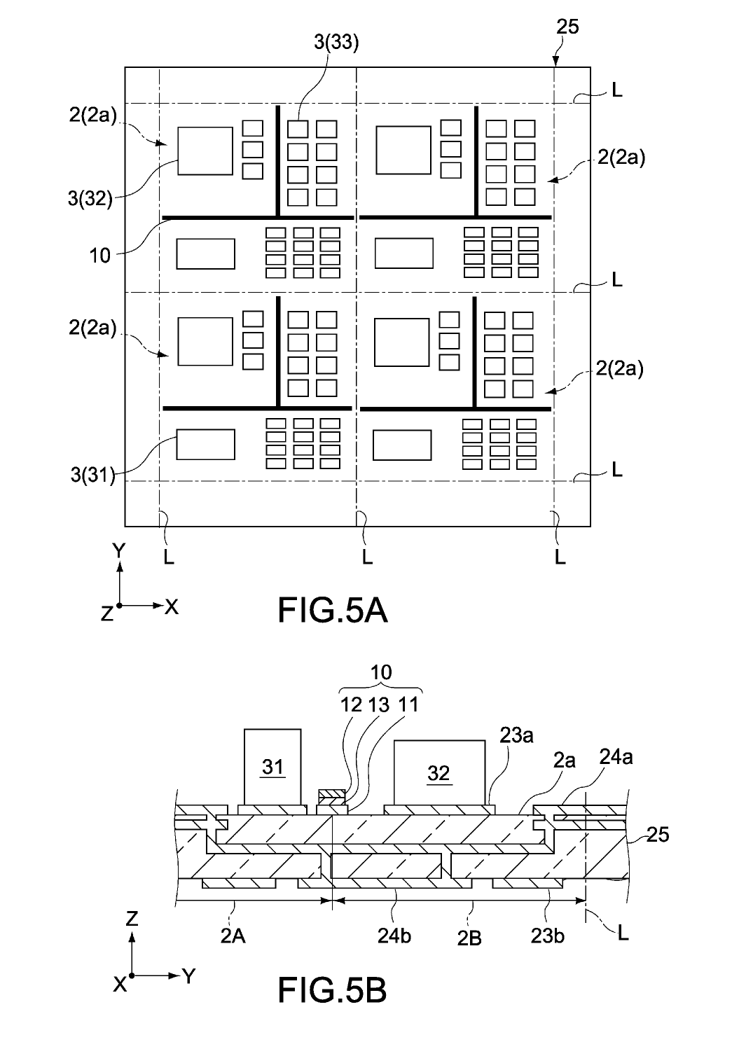

FIGS. 4 to 10 are diagrams for explaining the method of producing the circuit module 100. Moreover, in each of FIGS. 5 to 10, A is a top view, and B is a cross-sectional view of a main portion viewed from the X-axis direction. The method of producing the circuit module according to this embodiment includes a process of preparing an aggregate substrate, a process of mounting an electronic component, a process of forming a sealing layer, a half-cutting process, a process of forming a trench, a process of forming a conductive shield, and a cutting process. Hereinafter, each process will be described.

### (Process of Preparing Aggregate Substrate)

FIG. 4 is a top view schematically showing the configuration of an aggregate substrate 25. The aggregate substrate 25 includes a substrate with a large area on which a plurality of wiring substrates 2 are attached. FIG. 4 shows separation lines L dividing the plurality of wiring substrates 2. The separation line L may be a virtual line, and drawn on the aggregate substrate 25 actually by printing or the like.

It should be noted that in the example shown in FIG. 4, an example in which four wiring substrates 2 are cut from the aggregate substrate 25 is shown. The number of wiring substrates 2 to be cut is not particularly limited. For example, in the case where a substrate formed to have a substantially square shape of about 150 mm square is used as the aggregate substrate 25, four wiring substrates 2 of about 35 mm square are arranged in the X-axis direction and the Y-axis direction, i.e. sixteen wiring substrates 2 are arranged. Moreover, as the aggregate substrate 25, a substrate having a rectangular shape 100 to 200 mm on a side is typically used.

On the aggregate substrate 25, the conductive shield 5 is finally formed through each process to be described later. In the cutting process being the last process, the aggregate substrate 25 is cut (full-cut) along the separation line L to produce a plurality of circuit modules 100. Moreover, although not shown, in the aggregate substrate 25, a predetermined wiring pattern is formed for each area forming the wiring substrate 2.

The conductor pattern 10 including the first metal layer 11, the second metal layer 12, and the third metal layer 13 is formed along the boundary between areas on the wiring substrate 2. The method of forming the second metal layer 12 and the third metal layer 13 of the conductor pattern 10 is not particularly limited, and a vacuum deposition method such as a plating method or a sputtering method may be employed.

In this embodiment, the second metal layer 12 and the third metal layer 13 of the conductor pattern 10 are formed using the insulating protective layer 6 as a mask, as shown in FIG. 3. First, on the mount surface 2a of the wiring substrate 2, the protective layer 6 is formed by applying a resist material so as to cover the first metal layer 11 (upper layer wiring pattern 23a) and patterning the resist material into a predetermined shape. Next, by using the protective layer 6 as a mask, the third metal layer 13 and the second metal layer 12 are formed on the surface of the first metal layer 11 in the stated order by an electrolytic plating method or the like.

### (Process of Mounting Electronic Component)

FIGS. 5A and 5B are diagrams for explaining a process of mounting the electronic components 3 (31 to 33), and show a mode in which the electronic components 31 to 33 are disposed on the aggregate substrate 25 (wiring substrate 2).

In this process, the plurality of electronic components 31 to 33 are mounted on the first area 2A, the second area 2B, and the third area 2C on the mount surface 2a. As the method of mounting the electronic components 31 to 33, a reflow process is employed, for example. Specifically, first, a soldering paste is applied to a predetermined land portion on the mount surface 2a by a screen printing method or the like. Next, the plurality of electronic components 31 to 33 are mounted on the predetermined land portion via the soldering paste. After that, the aggregate substrate 25 on which the electronic components 31 to 33 are mounted is put in a reflow furnace, and the electronic components 31 to 33 are electrically and mechanically bonded to the mount surface 2a by performing a reflow process on the soldering paste.

### (Process of Forming Sealing Layer)

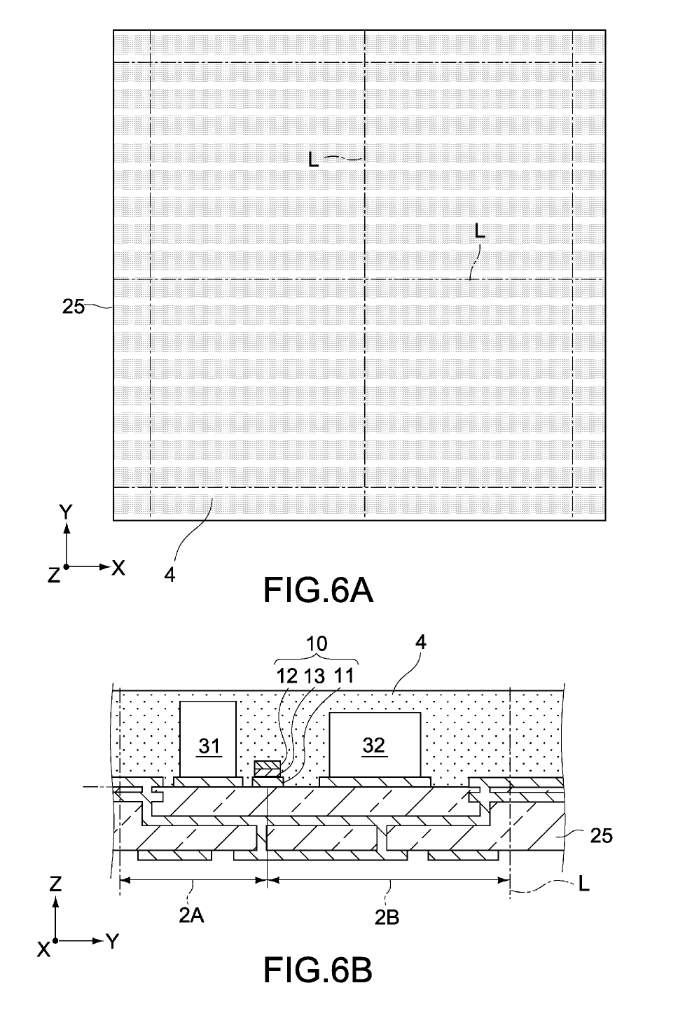

FIGS. 6A and 6B are diagrams for explaining a process of forming the sealing layer 4, and show a mode in which the sealing layer 4 is formed on the mount surface 2a.

The sealing layer 4 is formed on the mount surface 2a of the aggregate substrate 25 so as to cover the plurality of electronic components 31 to 33. The method of forming the sealing layer 4 is not particularly limited, and a molding method using a mold, a potting molding method using no mold, or the like can be applied, for example. Moreover, after a liquid or paste sealing resin material is applied to the mount surface 2a by a spin coating method or a screen printing method, heat treatment may be applied on it to be cured.

### (Half-Cut Process)

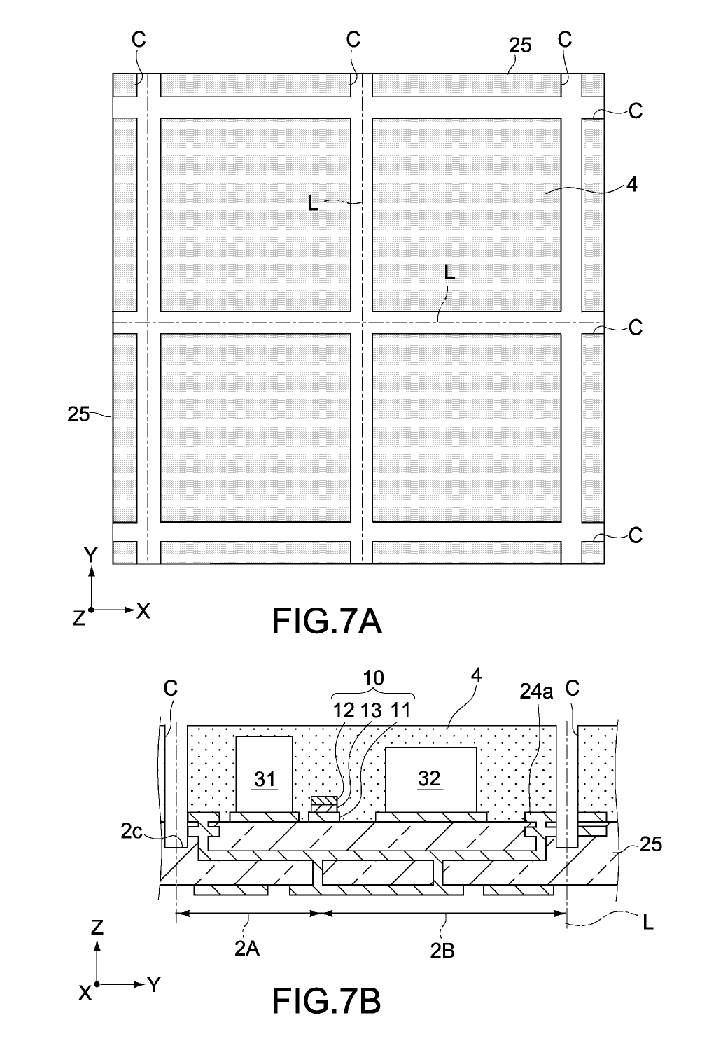

FIGS. 7A and 7B are diagrams showing a half-cut process. In this process, cut grooves C are formed along the separation line L to have a depth ranging from the upper surface of the sealing layer 4 to the inside of the aggregate substrate 25 by a dicer, for example. The cut groove C forms the uneven surface 2c of the aggregate substrate 25 (wiring substrate 2). The depth of the cut groove C is not particularly limited. However, the cut groove C is formed to have a depth such that the first GND terminal 24a on the aggregate substrate 25 can be divided.

### (Process of Forming Trench)

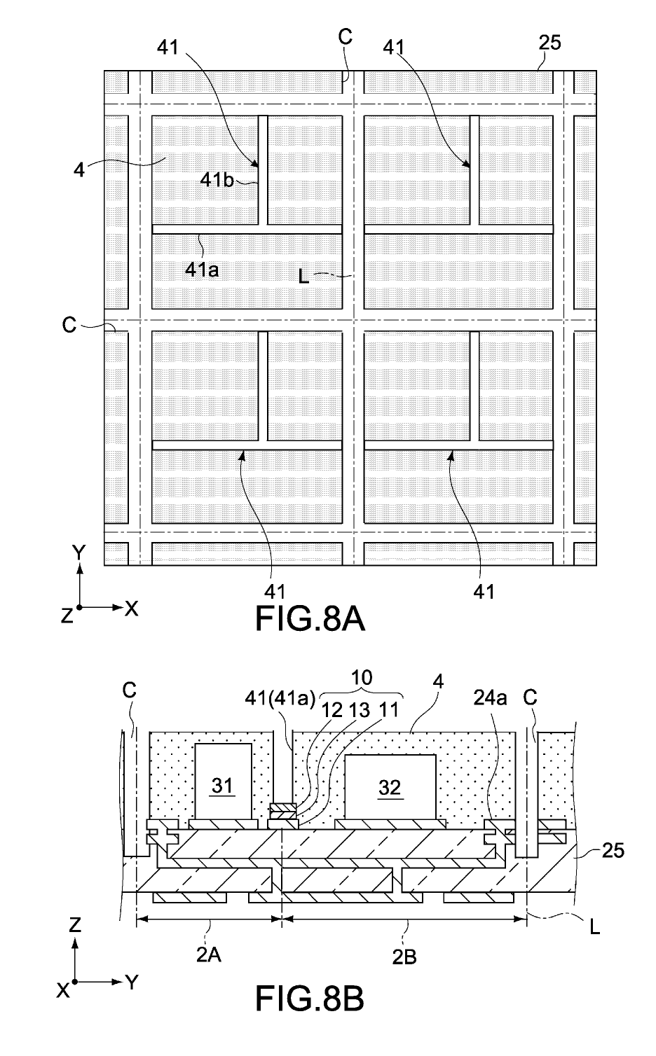

FIGS. 8A and 8B are diagrams for explaining a process of forming the trench 41. The trench 41 is formed along the boundary between the areas 2A to 2C on the mount surface 2a. Specifically, the trench 41 includes a trench 41a formed along the boundary between the first area 2A and the second and third areas 2B and 2C, and a second trench 41b formed along the boundary between the second area 2B and the third area 2C.

An Nd-YAG is used to form the trench 41. The laser beam may be a continuous wave or a pulse wave. The laser beam is applied, from the side of the upper surface of the sealing layer 4, to the area in which the second shield portion 52 is formed. The resin material of the area to be irradiated with the laser beam is removed by being partially molten or evaporated. The laser beam is scanned on the upper surface of the sealing layer 4 at constant power and speed, for example. Thus, the trenches 41 are formed to have almost equal depths. The number of times of scanning is not limited to one, and the scanning may be performed a plurality of times.

The width of the trench 41 is not particularly limited. However, the filling properties of the conductive resin forming the second shield portion 52 is reduced as the width is decreased, and the mounting area of the electronic components 3 is reduced and it is difficult to reduce the size of the module as the width is increased. In this embodiment, the width of the trench 41 is set to 0.05 to 0.3 mm.

The trench 41 is typically formed to have a depth such that the bottom of the trench 41 reaches the vicinity of the mount surface 2a. In this embodiment, the trench 41 is formed to have a depth such that the bottom of the trench 41 reaches the second metal layer 12 of the conductor pattern 10. Accordingly, the trench 41 having a depth such that the second metal layer 12 of the conductor pattern 10 is exposed to the sealing layer 4 is formed along the boundary between the areas 2A to 2C. At this time, the second metal layer 12 including Au or Ag having a relatively high reflectance rate and a relatively low absorption rate of a laser beam reflects the laser beam having reached the bottom of the trench 41. Accordingly, the first metal layer 11 disposed below the second metal layer 12 is effectively protected.

The procedure for forming the trench 41 is not particularly limited. The second trench 41b may be formed after the first trench 41a is formed, or the first trench 41a may be formed after the second trench 41b is formed. Moreover, the trench 41 may be formed prior to the half-cut process.

### (Process of Forming Conductive Shield)

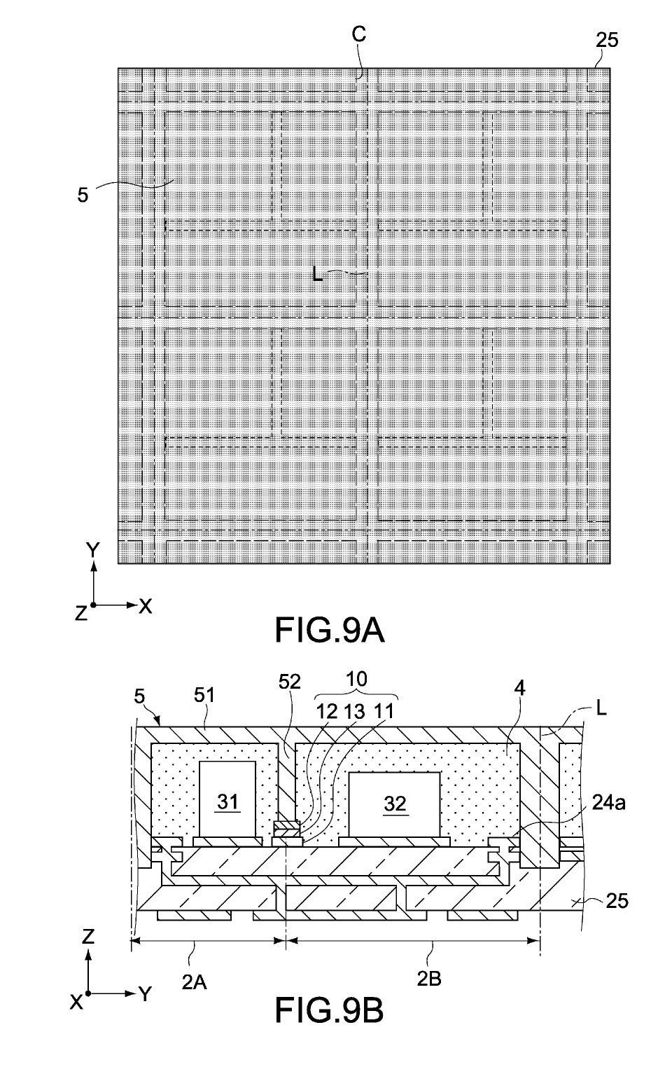

FIGS. 9A and 9B are diagrams for explaining a process of forming the conductive shield 5. The conductive shield 5 is formed on the sealing layer 4. Accordingly, the first shield portion 51 covering the outer surface of the sealing layer 4 and the second shield portion 52 provided on the trench 41 are formed.

In this embodiment, the conductive shield 5 is formed by applying or filling conductive resin or conductive paint to/in the surface of the sealing layer 4. The method of forming the conductive shield 5 is not particularly limited, and a molding method using a mold, a potting molding method using no mold, or the like can be applied, for example. Moreover, after a liquid or paste sealing resin material is applied to the sealing layer 4 by a spin coating method or a screen printing method, heat treatment may be applied on it to be cured. Moreover, in order to improve the efficiency of filling the conductive material in the trench 41, the process may be performed in a vacuum atmosphere.

The second shield portion 52 is filled in the trench 41. Accordingly, the second shield portion 52 is bonded to the second metal layer 12 of the conductor pattern 10, which is exposed at the bottom of the trench 41. In this embodiment, because the first shield portion 51 and the second shield portion 52 include the same material, electrical conduction between the first shield portion 51 and the second shield portion 52 and a desired joint strength between the shield portions 51 and 52 are ensured.

The conductive resin forming the first shield portion 51 is filled in also the cut groove C formed on the sealing layer 4, and thus the conductive resin is bonded to the first GND terminal 24a on the substrate 2 facing the cut groove C. Accordingly, the first shield portion 51 and the first GND terminal 24a are electrically and mechanically connected to each other.

The forming of the conductive shield 5 may be performed by a vacuum deposition method such as a plating method and a sputtering method. In the plating method, by immersing the aggregate substrate 25 in a plating bath and depositing a plated layer on the outer surface of the sealing layer 4 and the inner wall surface of the trench 41, it is possible to form the conductive shield 5. In the sputtering method, by putting the aggregate substrate 25 in a vacuum chamber and sputtering a target including a conductive material to deposit a sputtered layer on the outer surface of the sealing layer 4 and the inner wall surface of the trench 41, it is possible to form the conductive shield 5. In this case, there is no need to fill the trench 41 with the plated layer or the sputtered layer.

### (Cutting Process)

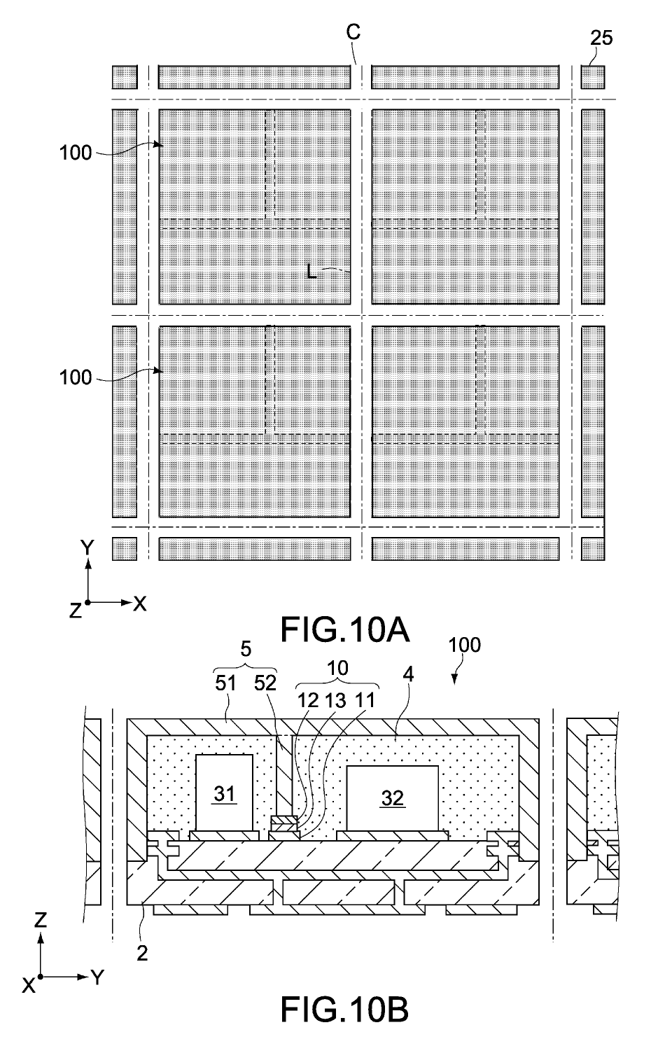

FIGS. 10A and 10B are diagrams for explaining a cutting process. In this process, the aggregate substrate 25 is full-cut along the separation line L, and thus divided into a plurality of circuit modules 100. For the separation, a dicer or the like is used. In this embodiment, because the conductive shield 5 is filled in the cut groove C, the aggregate substrate 25 is separated along the separation line L so that the wiring substrate 2 and the conductive shield 5 (first shield portion 51) have the same cut surface. Accordingly, the circuit module 100 including the conductive shield 5, which covers the surface (upper surface and side surface) of the sealing layer 4 and a part of the side surface of the wiring substrate 2, is produced.

### Operation of this Embodiment

Through the above-mentioned processes, the circuit module 100 is produced. According to the method of producing a circuit module according to this embodiment, it is possible to produce the circuit module 100 including the conductive shield 5, which includes the first shield portion 51 preventing an electromagnetic wave from leaking to the outside of the module and from entering from the outside and the second shield portion 52 preventing the plurality of electronic components in the module from electromagnetically interfering with each other.

Moreover, according to this embodiment, because a laser processing method is employed for forming the trench 41 of the sealing layer 4 on which the second shield portion 52 is provided, the trench 41 is formed to have an arbitrary shape (e.g., bent shape, zigzag shape, and curved shape) as compared with the case where the trench 41 is formed by a dicing process. Accordingly, the degree of freedom of designing of the second shield portion 52 is increased.

Moreover, in general, in the case where a groove is formed on the sealing layer by laser cutting, it is difficult to optimally adjust the laser power for processing only resin reliably without giving damage on the wiring pattern located on the bottom of the groove. Moreover, because smear (residue of resin or filler) remains at the bottom of the groove, there is a need to perform a desmear process as a post-step. As the desmear process, a method of physically removing by a dry etching or a method of chemically removing by using a strong alkaline liquid medicine or the like is used normally. However, it becomes more difficult to perform the processing as the aspect ratio (width/depth) of the groove increases. Therefore, favorable shielding properties are not ensured in some cases because the electrical connection with the wiring pattern located immediately below the groove is disturbed even if conductive resin is filled in the groove.

As a countermeasure, in this embodiment, the outermost layer of the conductor pattern 10 leading the second shield portion 52 to the GND terminal includes an Au layer or an Ag layer (second metal layer 12) having a relatively high reflectance rate of a laser beam. Therefore, because it is possible to prevent the conductor pattern 10 from being burned out even in the case where the laser power is too strong, it is possible to reduce the burden of control management of the laser power and to improve the workability and productivity. Moreover, it is possible to protect the first metal layer 11 against irradiation of the laser even if the process is performed with too strong laser power such that smear does not remain at the bottom of the groove. Furthermore, even in the case where the second metal layer 12 is burned out, the first metal layer 11 is protected by the third metal layer 13. Accordingly, it is possible to ensure the electrical conduction between the second shield portion 52 provided in the trench 41 and the first metal layer 11 and to reliably and easily form the trench 41 without burning out the first metal layer 11 by the laser beam.

Furthermore, in this embodiment, because the trench 41 is formed by a laser processing method, it is possible to achieve high accuracy of depth as compared with the case where the trench 41 is formed by a dicing process. Moreover, because the second metal layer 12 being the outermost layer of the conductor pattern 10 includes Au or Ag having high reflectance properties of a laser beam, it is possible to effectively protect the first metal layer 11 against being damaged by the laser and to protect the first metal layer 11 by the third metal layer 13 having heat resistance higher than the first metal layer 11 even if the second metal layer 12 is cut by the irradiation of the laser. As described above, according to this embodiment, because the conductor pattern 10 can be formed immediately below the trench 41, it is possible to provide the circuit module 100 with a high degree of freedom of designing of a wiring.

Although embodiments of the present disclosure have been described, the present disclosure is not limited to the above-mentioned embodiments and various modifications can be made based on the technical ideas of the present disclosure.

For example, in this embodiment, the example in which the wiring substrate 2 includes a print wiring substrate has been described. However, the wiring substrate 2 is not limited thereto, and may include a semiconductor substrate such as a silicon substrate. Moreover, the electronic components 3 may include various actuators such as MEMS (Micro Electro Mechanical System) components.

1. A circuit module, comprising:
a wiring substrate having a mount surface and a conductor pattern, the mount surface having a first area and a second area, the conductor pattern being formed along a boundary between the first area and the second area on the mount surface, an outermost layer of the conductor pattern including one of Au and Ag;
a plurality of electronic components mounted on the first area and the second area;
an insulating sealing layer having a trench with a depth such that at least a part of the outermost layer of the conductor pattern is exposed, the insulating sealing layer covering the plurality of electronic components, the trench being formed along the boundary; and
a conductive shield having a first shield portion and a second shield portion, the first shield portion covering an outer surface of the sealing layer, the second shield portion being formed in the trench, the second shield portion having a bottom connected to the outermost layer of the conductor pattern.

2. The circuit module according to claim 1, wherein
the wiring substrate further has a terminal surface on the opposite side of the mount surface, and
the conductor pattern is electrically connected to the terminal surface.

3. The circuit module according to claim 1, wherein
the wiring substrate further has an insulating protective layer covering the mount surface, and
the protective layer has an aperture from which at least a part of the outermost layer of the conductor pattern is exposed.

4. The circuit module according to claim 1, wherein
the conductor pattern has
a first metal layer including Cu, and
the outermost layer comprising a second metal layer including one of Au and Ag, the second metal layer being formed on a surface of the first metal layer.

5. The circuit module according to claim 4, wherein
the conductor pattern further has a third metal layer disposed between the first metal layer and the second metal layer, and
the third metal layer includes a metal material having a melting point higher than Cu.

6. The circuit module according to claim 1, wherein
the second shield portion includes a cured material of conductive resin filled in the trench.

7. The circuit module according to claim 1, wherein
the second shield portion includes one of a plated layer and a sputtered layer deposited on an inner wall of the trench.

8. The circuit module according to claim 1, wherein
the trench is formed by laser processing.

9. A method of producing a circuit module, comprising:
preparing a wiring substrate on which a conductor pattern is formed on a mount surface having a first area and a second area, the conductor pattern being formed along a boundary between the first area and the second area on the mount surface, the conductor pattern being electrically connected to a terminal surface on the opposite side of the mount surface;
forming one of an Au layer and an Ag layer on a surface of the conductor pattern;
mounting a plurality of electronic components on the first area and the second area;
forming a sealing layer including an insulating material on the mount surface, the sealing layer covering the plurality of electronic components;
forming a trench on the sealing layer along the boundary by applying a laser beam to a surface of the sealing layer, the trench having a depth such that at least a part of an outermost surface of the conductor pattern is exposed; and
forming a conductive shield by filling conductive resin in the trench and covering an outer surface of the sealing layer with conductive resin.

10. The method of producing a circuit module according to claim 9, wherein
the forming of one of the Au layer and the Ag layer includes
forming, on the mount surface, an insulating protective layer having an aperture from which at least a part of the outermost layer of the conductor pattern is exposed, and
forming one of the Au layer and the Ag layer using the protective layer as a mask.

11. The method of producing a circuit module according to claim 9, wherein
the trench is formed by applying an Nd:YAG laser beam to a surface of the sealing layer.

12. The method of producing a circuit module according to claim 9, wherein
the trench is formed by applying a CO₂ laser beam to a surface of the sealing layer.
